(19) United States
(12) Patent Application Publication
(10) Pub. No.: US 2024/0088641 A1
(43) Pub. Date: Mar. 14, 2024

(54) HIGH-RELIABILITY PROTECTION CIRCUIT AND POWER SUPPLY SYSTEM

(71) Applicant: INSPUR SUZHOU INTELLIGENT TECHNOLOGY CO., LTD., Suzhou, Jiangsu (CN)

(72) Inventors: Yunli LIU, Suzhou, Jiangsu (CN); Hui SUN, Suzhou, Jiangsu (CN)

(73) Assignee: INSPUR SUZHOU INTELLIGENT TECHNOLOGY CO., LTD., Suzhou, Jiangsu (CN)

(21) Appl. No.: 18/261,069

(22) PCT Filed: Nov. 30, 2021
(86) PCT No.: PCT/CN2021/134338

§ 371 Date: Jul. 11, 2023

(30) Foreign Application Priority Data
Aug. 12, 2021 (CN) 202110923617.0

(51) Int. Cl. H02H 3/08; H02H 1/00

(52) U.S. Cl. CPC H02H 3/08; H02H 1/0007

(57) ABSTRACT

This application discloses a high-reliability protection circuit and a power supply system. The high-reliability protection circuit includes: a load overcurrent voltage monitoring component detecting a load supply voltage of a load, and determining and outputting a first current abnormal signal; a control logic component receiving the first current abnormal signal and generating a turn-off control signal; a driving electrode charging charge pump component receiving the turn-off control signal and generating a driving electrode voltage control signal and a channel conduction parameter control signal; a driving electrode rapid discharge component receiving the driving electrode voltage control signal, and transmitting a power field effect transistor cut-off signal; and a power field effect transistor switch respectively receiving the channel conduction parameter control signal and the power field effect transistor cut-off signal, adjusting channel conduction parameters of the power field effect transistor switch, and cutting off a circuit main current. This application can rapidly monitor voltage changes when a far-end load current is abnormal, realize rapid protection specific to current abnormality, and avoid load-end chip or device damage accidents caused by current phase lag due to stray inductance.

### CROSS-REFERENCE TO RELATED APPLICATION

This application claims priority to Chinese Patent Application No. 202110923617.0, entitled “HIGH-RELIABILITY PROTECTION CIRCUIT AND POWER SUPPLY SYSTEM”, filed with China National Intellectual Property Administration on Aug. 12, 2021, which is incorporated herein by reference in its entirety.

### FIELD

This application relates to the field of power supply, and more particularly relates to a high-reliability protection circuit and a power supply system.

### BACKGROUND

With the development of new Internet technologies such as cloud computing, artificial intelligence (AI) and big data, the performance of servers has become increasingly high, and various high-precision chips have increasingly high requirements for current magnitude and power stability. The increasingly high demand for current is to obtain higher power and performance. However, the increase in demand for the current also brings hidden risks of abnormal current, and common abnormality of current includes overcurrent and short circuit. The overcurrent and short circuit will cause the chip to generate high heat inside, and consequently damage an internal semiconductor structure; and meanwhile, the overcurrent and the short circuit current will also cause high heat generated by a PCB copper foil outside the chip, which will damage devices adjacent to a path of a printed circuit board (PCB), and seriously will generate open fire causing serious accidents.

The prior art usually adopts a FUSE or E-FUSE solution for current protection, and an input end is connected with a protective device in series, which is equivalent to additional arrangement of a power MOS (field effect transistor) device on a current monitor controller; and when the current monitor controller monitors overcurrent or high current at the input end, a turn-off command is transmitted to the power MOS device, such that rear-end current supply is cut off.

The solutions in the prior art can only perform current judgment based on front-end current monitoring. But, in practical application, due to a large area of a board and a too long power supply path, high impedance, stray capacitance and stray inductance will exist, and thus, when the current suddenly overloads or shorts, the stray capacitance will change the phase of the voltage and the current, such that the change of the current phase lags behind the change of the voltage phase by 90 degrees. The current lag reflected the current monitor controller at the power supply end means that the actual current on the rear-end chip side possibly reaches a higher point than a point monitored by the current monitor controller, which may cause unrecoverable damage or burnout of the chip or board.

In conclusion, the existing solutions have a certain delay in protective action in the process of transmitting current abnormality to the current monitor device and then acting on power MOS turn-off when the current suddenly overloads or shorts. There are still no effective solutions for the problems about delay in current overload detection in the prior art.

### SUMMARY

On that basis, an objective of an embodiment of this application is to provide a high-reliability protection circuit, which can rapidly monitor voltage changes when a far-end load current is abnormal, realize rapid protection specific to current abnormality, and avoid load-end chip or device damage accidents caused by current phase lag due to stray inductance.

Based on the above objective, a first aspect of this embodiment of this application provides a high-reliability protection circuit, including:
a load overcurrent voltage monitoring component, which is connected to two ends of a load in parallel so as to detect a load supply voltage of the load, and determines and outputs a first current abnormal signal based on the load supply voltage;
a control logic component, which is electrically connected to the load overcurrent voltage monitoring component so as to receive the first current abnormal signal and generates a turn-off control signal based on the first current abnormal signal;
a driving electrode charging charge pump component, which is electrically connected to the control logic component so as to receive the turn-off control signal, and generates a driving electrode voltage control signal and a channel conduction parameter control signal based on the turn-off control signal;
a driving electrode rapid discharge component, which is electrically connected to the driving electrode charging charge pump component so as to receive the driving electrode voltage control signal, and transmits a power field effect transistor cut-off signal based on the driving electrode voltage control signal; and
a power field effect transistor switch, which is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off a circuit main current based on the power field effect transistor cut-off signal.

In some implementations, the circuit further includes a front-end current monitoring component, which is electrically connected to a power supply end so as to collect the circuit main current, and generates a second current abnormal signal based on the main current.

In some implementations, the control logic component is further electrically connected to the front-end current monitoring component so as to receive the second current abnormal signal, and generates the turn-off control signal based on the first current abnormal signal and the second current abnormal signal.

In some implementations, the load overcurrent voltage monitoring component includes:
a near-end supply voltage feedback component, which is connected to two ends of a near-end load in parallel so as to detect a near-end load supply voltage of the near-end load;
a far-end supply voltage feedback component, which is connected to two ends of a far-end load in parallel so as to detect a far-end load supply voltage of the far-end load; and
an H-bridge capacitor voltage difference feedback component, which is electrically connected to the near-end supply voltage feedback component and the far-end supply voltage feedback component so as to acquire the near-end load supply voltage and the far-end load supply voltage, and determines and outputs the first current abnormal signal based on the near-end load supply voltage and the far-end load supply voltage.

In some implementations, both the near-end supply voltage feedback component and the far-end supply voltage feedback component are pure resistive circuits, both the near-end supply voltage feedback component and the far-end supply voltage feedback component include voltage divider resistors, and resistance values of the voltage divider resistors are determined based on a total voltage of the circuit.

In some implementations, the H-bridge capacitor voltage difference feedback component includes a differential comparator amplifier, and is further configured to determine a far-end and near-end load supply voltage difference based on the near-end load supply voltage and the far-end load supply voltage, and the differential comparator amplifier is used to amplify the far-end and near-end load supply voltage difference to serve as the first current abnormal signal to be output.

In some implementations, the control logic component is further configured to compare the amplified far-end and near-end load supply voltage difference and a preset far-end and near-end voltage difference threshold, outputs, in response to the amplified far-end and near-end load supply voltage difference exceeding the far-end and near-end voltage difference threshold, the turn-off control signal for instructing to turn off the power field effect transistor switch, and outputs, in response to the amplified far-end and near-end load supply voltage difference not exceeding the far-end and near-end voltage difference threshold, the turn-off control signal for instructing to keep turn-on of the power field effect transistor switch.

In some implementations, the channel conduction parameters include whether a channel of the power field effect transistor switch is conducted or not, a conduction degree of the channel, and a cutoff speed of the channel.

In some implementations, the power field effect transistor switch is further configured to instruct cutoff of the circuit main current in response to the power field effect transistor cut-off signal, such that a driving electrode of the power field effect transistor switch discharges a driving electrode voltage of the power field effect transistor switch with the cutoff speed of the channel so as to reach the conduction degree of the channel, thereby cutting off the circuit main current.

A second aspect of this embodiment of this application provides a high-reliability power supply system, including:
a power supply end;
a load, including a near-end load and a far-end load; and
a high-reliability protection circuit which is electrically connected to the power supply end and the load, such that the power supply end supplies power to the load and provides high-reliability power supply protection.

In some implementations, the high-reliability protection circuit includes:
a load overcurrent voltage monitoring component, which is connected to two ends of a load in parallel so as to detect a load supply voltage of the load, and determines and outputs a first current abnormal signal based on the load supply voltage;
a control logic component, which is electrically connected to the load overcurrent voltage monitoring component so as to receive the first current abnormal signal and generates a turn-off control signal based on the first current abnormal signal;
a driving electrode charging charge pump component, which is electrically connected to the control logic component so as to receive the turn-off control signal, and generates a driving electrode voltage control signal and a channel conduction parameter control signal based on the turn-off control signal;
a driving electrode rapid discharge component, which is electrically connected to the driving electrode charging charge pump component so as to receive the driving electrode voltage control signal, and transmits a power field effect transistor cut-off signal based on the driving electrode voltage control signal; and
a power field effect transistor switch, which is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off a circuit main current based on the power field effect transistor cut-off signal.

In some implementations, the circuit further includes a front-end current monitoring component, which is electrically connected to the power supply end so as to collect the circuit main current, and generates a second current abnormal signal based on the main current.

In some implementations, the control logic component is further electrically connected to the front-end current monitoring component so as to receive the second current abnormal signal, and generates the turn-off control signal based on the first current abnormal signal and the second current abnormal signal.

In some implementations, the load overcurrent voltage monitoring component includes:
a near-end supply voltage feedback component, which is connected to two ends of a near-end load in parallel so as to detect a near-end load supply voltage of the near-end load;
a far-end supply voltage feedback component, which is connected to two ends of a far-end load in parallel so as to detect a far-end load supply voltage of the far-end load; and
an H-bridge capacitor voltage difference feedback component, which is electrically connected to the near-end supply voltage feedback component and the far-end supply voltage feedback component so as to acquire the near-end load supply voltage and the far-end load supply voltage, and determines and outputs the first current abnormal signal based on the near-end load supply voltage and the far-end load supply voltage.

In some implementations, both the near-end supply voltage feedback component and the far-end supply voltage feedback component are pure resistive circuits, both the near-end supply voltage feedback component and the far-end supply voltage feedback component include voltage divider resistors, and resistance values of the voltage divider resistors are determined based on a total voltage of the circuit.

In some implementations, the H-bridge capacitor voltage difference feedback component includes a differential comparator amplifier, and is further configured to determine a far-end and near-end load supply voltage difference based on the near-end load supply voltage and the far-end load supply voltage, and the differential comparator amplifier is used to amplify the far-end and near-end load supply voltage difference to serve as the first current abnormal signal to be output.

In some implementations, the control logic component is further configured to compare the amplified far-end and near-end load supply voltage difference and a preset far-end and near-end voltage difference threshold, outputs, in response to the amplified far-end and near-end load supply voltage difference exceeding the far-end and near-end voltage difference threshold, the turn-off control signal for instructing to turn off the power field effect transistor switch, and outputs, in response to the amplified far-end and near-end load supply voltage difference not exceeding the far-end and near-end voltage difference threshold, the turn-off control signal for instructing to keep turn-on of the power field effect transistor switch.

In some implementations, the channel conduction parameters include whether a channel of the power field effect transistor switch is conducted or not, a conduction degree of the channel, and a cutoff speed of the channel.

In some implementations, the power field effect transistor switch is further configured to instruct cutoff of the circuit main current in response to the power field effect transistor cut-off signal, such that a driving electrode of the power field effect transistor switch discharges a driving electrode voltage of the power field effect transistor switch with the cutoff speed of the channel so as to reach the conduction degree of the channel, thereby cutting off the circuit main current.

This application has the following beneficial effects that the high-reliability protection circuit provided by this embodiment of this application adopts the technical solution that the load overcurrent voltage monitoring component is used and connected to the two ends of the load in parallel so as to detect the load supply voltage of the load, and determines and outputs the first current abnormal signal based on the load supply voltage; the control logic component is electrically connected to the load overcurrent voltage monitoring component so as to receive the first current abnormal signal, and generates the turn-off control signal based on the first current abnormal signal; the driving electrode charging charge pump component is electrically connected to the control logic component so as to receive the turn-off control signal, and generates the driving electrode voltage control signal and the channel conduction parameter control signal based on the turn-off control signal; the driving electrode rapid discharge component is electrically connected to the driving electrode charging charge pump component so as to receive the driving electrode voltage control signal, and transmits the power field effect transistor cut-off signal based on the driving electrode voltage control signal; and the power field effect transistor switch is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off the circuit main current based on the power field effect transistor cut-off signal, such that the voltage changes when the far-end load current is abnormal can be rapidly monitored, rapid protection specific to current abnormality is realized, and load-end chip or device damage accidents caused by current phase lag due to the stray inductance are avoided.

### BRIEF DESCRIPTION OF THE DRAWINGS

In order to describe solutions in embodiments of this application or in the prior art more clearly, drawings required to be used in descriptions of the embodiments or the prior art will be briefly introduced below, it is apparent that the drawings described below are only some embodiments of this application, and those of ordinary skill in the art can obtain other drawings according to these drawings without creative work.

FIG. 1 is a structural schematic diagram of a high-reliability protection circuit according to this application; and

FIG. 2 is a circuit schematic diagram of the high-reliability protection circuit according to this application.

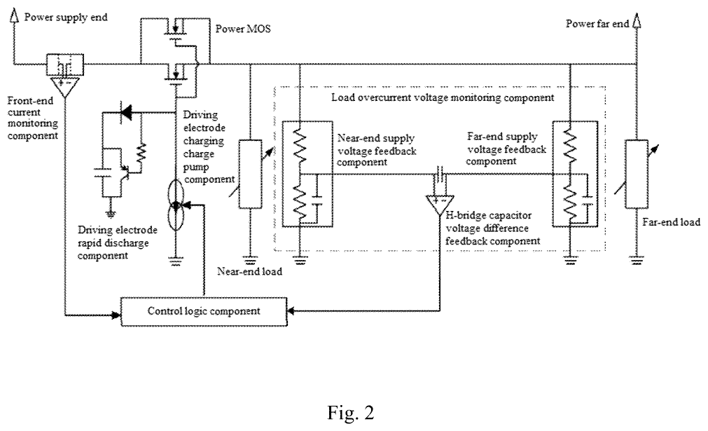

### DETAILED DESCRIPTION OF THE EMBODIMENTS

To make purposes, solutions and advantages of this application more clearly understood, the embodiments of this application are further described in detail by combining specific embodiments and with reference to drawings.

It should be noted that expressions of “first” and “second” used in the embodiments of this application are intended to distinguish two different entities or parameters with the same name, and it is apparent that “first” and “second” facilitate descriptions only but cannot be understood as limiting on the embodiments of this application, which will not be described in detail in subsequent embodiments.

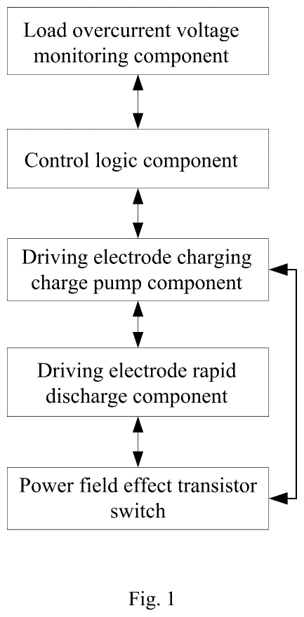

Based on the above purposes, a first aspect of an embodiment of this application provides an embodiment of a high-reliability protection circuit capable of rapidly monitoring voltage changes when a far-end load current is abnormal, and realizing rapid protection specific to the current abnormality. FIG. 1 illustrates a structural schematic diagram of a first embodiment of a high-reliability protection circuit according to this application.

As shown in FIG. 1, the high-reliability protection circuit includes:
a load overcurrent voltage monitoring component, which is connected to two ends of a load in parallel so as to detect a load supply voltage of the load, and determines and outputs a first current abnormal signal based on the load supply voltage;
a control logic component, which is electrically connected to the load overcurrent voltage monitoring component so as to receive the first current abnormal signal and generates a turn-off control signal based on the first current abnormal signal;
a driving electrode charging charge pump component, which is electrically connected to the control logic component so as to receive the turn-off control signal, and generates, based on the turn-off control signal, a driving electrode voltage control signal and a channel conduction parameter control signal;
a driving electrode rapid discharge component, which is electrically connected to the driving electrode charging charge pump component so as to receive the driving electrode voltage control signal, and transmits a power field effect transistor cut-off signal based on the driving electrode voltage control signal; and
a power field effect transistor switch, which is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off a circuit main current based on the power field effect transistor cut-off signal.

Apparatuses, devices, etc. disclosed by this application may be various terminal devices, such as a mobile phone, a personal digital assistant (PDA), a portable android device (PAD) and a smart television, and may also be a large terminal device, such as a server, and thus, the scope of protection disclosed by this embodiment of this application should not be limited to any specific type of apparatus and device. A client disclosed by this embodiment of this application may be applied to any above electronic terminal device in the form of electric hardware, computer software or a combination of both.

In some implementations, the circuit further includes a front-end current monitoring component, which is electrically connected to a power supply end so as to collect the circuit main current, and generates a second current abnormal signal based on the main current.

In some implementations, the control logic component is further electrically connected to the front-end current monitoring component so as to receive the second current abnormal signal, and generates the turn-off control signal based on the first current abnormal signal and the second current abnormal signal.

In some implementations, the load overcurrent voltage monitoring component includes:
a near-end supply voltage feedback component, which is connected to two ends of a near-end load in parallel so as to detect a near-end load supply voltage of the near-end load;
a far-end supply voltage feedback component, which is connected to two ends of a far-end load in parallel so as to detect a far-end load supply voltage of the far-end load; and
an H-bridge capacitor voltage difference feedback component, which is electrically connected to the near-end supply voltage feedback component and the far-end supply voltage feedback component so as to acquire the near-end load supply voltage and the far-end load supply voltage, and determines and outputs the first current abnormal signal based on the near-end load supply voltage and the far-end load supply voltage.

The H-bridge capacitor voltage difference feedback component involved in this application is essentially a differential circuit. In the prior art, an H-bridge sometimes refers to a structure formed by butt joint of two transistors, pins connecting the two transistors constitute a transverse line in the middle of the H, and pins respectively connected to other components constitute a left side and a right side of the H. The H-bridge capacitor voltage difference feedback component is the same with the H-bridge, has an H-shaped topology structure in a circuit schematic diagram, and thus, is called the H-bridge capacitor voltage difference feedback component.

In some implementations, both the near-end supply voltage feedback component and the far-end supply voltage feedback component are pure resistive circuits, both the near-end supply voltage feedback component and the far-end supply voltage feedback component include voltage divider resistors, and resistance values of the voltage divider resistors are determined based on a total voltage of the circuit.

In some implementations, the H-bridge capacitor voltage difference feedback component includes a differential comparator amplifier, and is further configured to determine a far-end and near-end load supply voltage difference based on the near-end load supply voltage and the far-end load supply voltage, and the differential comparator amplifier is used to amplify the far-end and near-end load supply voltage difference to serve as the first current abnormal signal to be output.

In some implementations, the control logic component is further configured to compare the amplified far-end and near-end load supply voltage difference and a preset far-end and near-end voltage difference threshold, outputs, in response to the amplified far-end and near-end load supply voltage difference exceeding the far-end and near-end voltage difference threshold, the turn-off control signal for instructing to turn off the power field effect transistor switch, and outputs, in response to the amplified far-end and near-end load supply voltage difference not exceeding the far-end and near-end voltage difference threshold, the turn-off control signal for instructing to keep turn-on of the power field effect transistor switch.

In some implementations, the channel conduction parameters include whether a channel of the power field effect transistor switch is conducted or not, a conduction degree of the channel, and a cutoff speed of the channel.

In some implementations, the power field effect transistor switch is further configured to instruct cutoff of the circuit main current in response to the power field effect transistor cut-off signal, such that a driving electrode of the power field effect transistor switch discharges a driving electrode voltage of the power field effect transistor switch with the cutoff speed of the channel so as to reach the conduction degree of the channel, thereby cutting off the circuit main current.

A current abnormality protection design method in the prior art realizes rear-end current protection only through front-end current monitoring. But when there are many rear-end system components, a path is long and stray inductance is large, the short-time transient high current at the far end will cause front-end monitoring current phase lag due to the stray inductance, and when the abnormal current is increasingly high, there will be a certain delay from far-end transient overcurrent and short-circuit abnormality caused by the stray inductance to front-end protection, and at the time, the far-end chip may have been damaged to a great degree.

Correspondingly, this embodiment of this application may realize following functions:
1) an accurate current value monitoring function is realized through the optional front-end current monitoring component;
2) the driving electrode charging charge pump component provides and controls the voltage of the driving electrode so as to control turn-on and turn-off of the MOS, and an opening degree and a closing speed of the channel;
3) when the MOS is required to be turned off, the rapid discharge component rapidly discharges a GATE charge, rapidly acts and stops continuous conduction of the current;
4) near-end and far-end voltage abnormality is monitored by utilizing a near-end voltage feedback component and a far-end voltage feedback component in the load overcurrent voltage monitoring component according to a character that a voltage in an inductive circuit leads a current, and then the faster protection action on the far-end load current abnormality is realized; and through adjustment on a voltage threshold of the near-end voltage feedback component and the far-end voltage feedback component, protection actions under two abnormal situations of slow overcurrent and transient overcurrent can be realized at the same time; and
5) the control logic component receives a current difference signal of the load overcurrent voltage monitoring component, compares a received far-end and near-end voltage difference and the preset threshold, and judges occurrence of the abnormal current; and meanwhile, the control logic component also receives current information of the front-end current monitoring component, realizes a function of monitoring an external current value or power, and constitutes dual protection with the load overcurrent voltage monitoring component.

The current abnormality protection circuit according to this embodiment of this application is designed to respectively have the near-end supply voltage feedback component and a far-end load overcurrent voltage feedback component, and the two components jointly constitute the load overcurrent voltage monitoring component; and the near-end voltage feedback component and the far-end voltage feedback component both adopt the pure resistive circuit design, adjustment is performed through the voltage divider resistors so as to adapt to systems with different input voltages, a filter capacitive device is additionally arranged in a voltage feedback device so as to reduce errors caused by accidental disturbance, and the pure resistive circuits can greatly reduce lag influences caused by inductive parameters.

Signals of the near-end voltage feedback component and the far-end voltage feedback component are H-bridge capacitor voltage difference feedback signals, when the far-end load has overcurrent, the voltage at the far-end voltage feedback position will drop while the voltage at the near-end voltage feedback position is basically consistent to the supply voltage, and thus, the voltage difference between the far-end voltage and the near-end voltage is formed. The voltage phase leads the current in the inductive circuit, changes of the far-end voltage and the near-end voltage can be rapidly monitored, and thus, the H-bridge capacitor voltage feedback manner is adopted to monitor the voltage changes under the far-end abnormal current. The changes of the voltage difference between two ends of an H-bridge capacitor are fed back to the control logic component, and partial voltage fed back by the near-end voltage and the far-end voltage may vary by adjusting the threshold so as to achieve applications of different abnormal current protection points.

An input control signal of the driving electrode charging charge pump component is connected to the control logic component, an output end is connected to the driving GATE of the MOS, and a grounding end is connected to a circuit earth. A rapid discharge circuit is connected to the driving GATE of the power MOS. When the driving electrode charging charge pump component transmits an instruction for turning off the MOS, the rapid discharge circuit rapidly acts due to drop of the voltage of the driving electrode so as to discharge the charge of the driving electrode, thereby achieving the functions of rapidly turning off or on the MOS, and accordingly stopping the continuous rear-end abnormal current.

A control logic component input signal includes a current monitoring signal of the front-end current monitoring component and a far-end voltage difference signal of the load overcurrent voltage monitoring component, the two signals may be logically and independently monitored, protection actions are performed, and the two signals may also be combined to realize more comprehensive protection. A control logic component output signal is a power MOS GATE drive signal, to realize a normal startup conduction action of the MOS and the protection action when the current is abnormal.

According to this embodiment of this application, the accurate current value monitoring function is realized through the optional front-end current monitoring component; the driving electrode charging charge pump component provides and controls the voltage of the driving electrode so as to control turn-on and turn-off of the MOS, and the opening degree and the closing speed of the channel; when the MOS is required to be turned off, the rapid discharge component rapidly discharges the GATE charge, rapidly acts and stops continuous conduction of the current; near-end and far-end voltage abnormality is monitored by utilizing the near-end voltage feedback component and the far-end voltage feedback component in the load overcurrent voltage monitoring component according to the character that the voltage in the inductive circuit leads the current, and then the faster protection action on the far-end load current abnormality is realized; and through adjustment on the voltage threshold of the near-end voltage feedback component and the far-end voltage feedback component, protection actions under two abnormal situations of slow overcurrent and transient overcurrent can be realized at the same time; and the control logic component receives the current difference signal of the load overcurrent voltage monitoring component, compares the received far-end and near-end voltage difference and the preset threshold, and judges occurrence of the abnormal current; and meanwhile, the control logic component also receives the current information of the front-end current monitoring component, realizes the function of monitoring the external current value or power, and constitutes dual protection with the load overcurrent voltage monitoring component. This application can effectively solve the problems about current abnormality monitoring caused by current phase lag due to stray inductance and load-end chip or device damage accidents caused by untimely protection during power supply of the server and a computer.

It can be seen from the above embodiment that the high-reliability protection circuit provided by this embodiment of this application adopts the technical solution that the load overcurrent voltage monitoring component is used and connected to the two ends of the load in parallel so as to detect the load supply voltage of the load, and determines and outputs the first current abnormal signal based on the load supply voltage; the control logic component is electrically connected to the load overcurrent voltage monitoring component so as to receive the first current abnormal signal, and generates the turn-off control signal based on the first current abnormal signal; the driving electrode charging charge pump component is electrically connected to the control logic component so as to receive the turn-off control signal, and generates the driving electrode voltage control signal and the channel conduction parameter control signal based on the turn-off control signal; the driving electrode rapid discharge component is electrically connected to the driving electrode charging charge pump component so as to receive the driving electrode voltage control signal, and transmits the power field effect transistor cut-off signal based on the driving electrode voltage control signal; and the power field effect transistor switch is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off the circuit main current based on the power field effect transistor cut-off signal, such that the voltage changes when the far-end load current is abnormal can be rapidly monitored, rapid protection specific to current abnormality is realized, and load-end chip or device damage accidents caused by current phase lag due to the stray inductance are avoided.

Based on the above purpose, a second aspect of this embodiment of this application provides an embodiment of a high-reliability power supply system. The high-reliability power supply system includes:
a power supply end;
a load, including a near-end load and a far-end load; and
a high-reliability protection circuit which is electrically connected to the power supply end and the load, such that the power supply end supplies power to the load and provides high-reliability power supply protection.

In some implementations, the high-reliability protection circuit includes:
a load overcurrent voltage monitoring component, which is connected to two ends of the load in parallel so as to detect a load supply voltage of the load, and determines and outputs a first current abnormal signal based on the load supply voltage;
a control logic component, which is electrically connected to the load overcurrent voltage monitoring component so as to receive the first current abnormal signal and generates a turn-off control signal based on the first current abnormal signal;
a driving electrode charging charge pump component, which is electrically connected to the control logic component so as to receive the turn-off control signal, and generates, based on the turn-off control signal, a driving electrode voltage control signal and a channel conduction parameter control signal;
a driving electrode rapid discharge component, which is electrically connected to the driving electrode charging charge pump component so as to receive the driving electrode voltage control signal, and transmits a power field effect transistor cut-off signal based on the driving electrode voltage control signal; and
a power field effect transistor switch, which is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off a circuit main current based on the power field effect transistor cut-off signal.

In some implementations, the circuit further includes a front-end current monitoring component, which is electrically connected to the power supply end so as to collect the circuit main current, and generates a second current abnormal signal based on the main current.

In some implementations, the control logic component is further electrically connected to the front-end current monitoring component so as to receive the second current abnormal signal, and generates the turn-off control signal based on the first current abnormal signal and the second current abnormal signal.

In some implementations, the load overcurrent voltage monitoring component includes:
a near-end supply voltage feedback component, which is connected to two ends of the near-end load in parallel so as to detect a near-end load supply voltage of the near-end load;
a far-end supply voltage feedback component, which is connected to two ends of the far-end load in parallel so as to detect a far-end load supply voltage of the far-end load; and
an H-bridge capacitor voltage difference feedback component, which is electrically connected to the near-end supply voltage feedback component and the far-end supply voltage feedback component so as to acquire the near-end load supply voltage and the far-end load supply voltage, and determines and outputs the first current abnormal signal based on the near-end load supply voltage and the far-end load supply voltage.

In some implementations, both the near-end supply voltage feedback component and the far-end supply voltage feedback component are pure resistive circuits, both the near-end supply voltage feedback component and the far-end supply voltage feedback component include voltage divider resistors, and resistance values of the voltage divider resistors are determined based on a total voltage of the circuit.

In some implementations, the H-bridge capacitor voltage difference feedback component includes a differential comparator amplifier, and is further configured to determine a far-end and near-end load supply voltage difference based on the near-end load supply voltage and the far-end load supply voltage, and the differential comparator amplifier is used to amplify the far-end and near-end load supply voltage difference to serve as the first current abnormal signal to be output.

In some implementations, the control logic component is further configured to compare the amplified far-end and near-end load supply voltage difference and a preset far-end and near-end voltage difference threshold, outputs, in response to the amplified far-end and near-end load supply voltage difference exceeding the far-end and near-end voltage difference threshold, the turn-off control signal for instructing to turn off the power field effect transistor switch, and outputs, in response to the amplified far-end and near-end load supply voltage difference not exceeding the far-end and near-end voltage difference threshold, the turn-off control signal for instructing to keep turn-on of the power field effect transistor switch.

In some implementations, the channel conduction parameters include whether a channel of the power field effect transistor switch is conducted or not, a conduction degree of the channel, and a cutoff speed of the channel.

In some implementations, the power field effect transistor switch is further configured to instruct cutoff of the circuit main current in response to the power field effect transistor cut-off signal, such that a driving electrode of the power field effect transistor switch discharges a driving electrode voltage of the power field effect transistor switch with the cutoff speed of the channel so as to reach the conduction degree of the channel, thereby cutting off the circuit main current.

It can be seen from the above embodiment that the high-reliability power supply system provided by this embodiment of this application adopts the technical solution that the load overcurrent voltage monitoring component is used and connected to the two ends of the load in parallel so as to detect the load supply voltage of the load, and determines and outputs the first current abnormal signal based on the load supply voltage; the control logic component is electrically connected to the load overcurrent voltage monitoring component so as to receive the first current abnormal signal, and generates the turn-off control signal based on the first current abnormal signal; the driving electrode charging charge pump component is electrically connected to the control logic component so as to receive the turn-off control signal, and generates the driving electrode voltage control signal and the channel conduction parameter control signal based on the turn-off control signal; the driving electrode rapid discharge component is electrically connected to the driving electrode charging charge pump component so as to receive the driving electrode voltage control signal, and transmits the power field effect transistor cut-off signal based on the driving electrode voltage control signal; and the power field effect transistor switch is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off the circuit main current based on the power field effect transistor cut-off signal, such that the voltage changes when the far-end load current is abnormal can be rapidly monitored, rapid protection specific to current abnormality is realized, and load-end chip or device damage accidents caused by current phase lag due to the stray inductance are avoided.

Those of ordinary skill in the art should understand that the discussion about any above embodiment is exemplary and is not intended to imply that the scope (including the claims) of the disclosure of the embodiments of this application is limited to these examples; and under the idea of the embodiments of this application, technical features in the above embodiments or in different embodiments may also be combined while many other changes of different aspects in the above embodiments of this application exist, and for brevity, are not provided in detail. Thus, any omission, modification, equivalent substitution, improvement, etc., made within the spirit and principle of the embodiments of this application shall fall within the scope of protection of the embodiments of this application.

1. A high-reliability protection circuit, comprising:
a load overcurrent voltage monitoring component, which is connected to two ends of a load in parallel so as to detect a load supply voltage of the load, and determines and outputs a first current abnormal signal based on the load supply voltage;
a control logic component, which is electrically connected to the load overcurrent voltage monitoring component so as to receive the first current abnormal signal and generates a turn-off control signal based on the first current abnormal signal;
a driving electrode charging charge pump component, which is electrically connected to the control logic component so as to receive the turn-off control signal, and generates a driving electrode voltage control signal and a channel conduction parameter control signal based on the turn-off control signal;
a driving electrode rapid discharge component, which is electrically connected to the driving electrode charging charge pump component so as to receive the driving electrode voltage control signal, and transmits a power field effect transistor cut-off signal based on the driving electrode voltage control signal; and
a power field effect transistor switch, which is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off a circuit main current based on the power field effect transistor cut-off signal.

2. The circuit according to claim 1, comprising:
a front-end current monitoring component, which is electrically connected to a power supply end so as to collect the circuit main current, and generates a second current abnormal signal based on the main current.

3. The circuit according to claim 2, wherein the control logic component is electrically connected to the front-end current monitoring component so as to receive the second current abnormal signal, and generates a turn-off control signal based on the first current abnormal signal and the second current abnormal signal.

4. The circuit according to claim 1, wherein the load overcurrent voltage monitoring component comprises:
a near-end supply voltage feedback component, which is connected to two ends of a near-end load in parallel so as to detect a near-end load supply voltage of the near-end load;
a far-end supply voltage feedback component, which is connected to two ends of a far-end load in parallel so as to detect a far-end load supply voltage of the far-end load; and
an H-bridge capacitor voltage difference feedback component, which is electrically connected to the near-end supply voltage feedback component and the far-end supply voltage feedback component so as to acquire the near-end load supply voltage and the far-end load supply voltage, and determines and outputs the first current abnormal signal based on the near-end load supply voltage and the far-end load supply voltage.

5. The circuit according to claim 4, wherein both the near-end supply voltage feedback component and the far-end supply voltage feedback component are pure resistive circuits, both the near-end supply voltage feedback component and the far-end supply voltage feedback component comprise voltage divider resistors, and resistance values of the voltage divider resistors are determined based on a total voltage of the circuit.

6. The circuit according to claim 4, wherein the H-bridge capacitor voltage difference feedback component comprises a differential comparator amplifier, and is configured to determine a far-end and near-end load supply voltage difference based on the near-end load supply voltage and the far-end load supply voltage, and the differential comparator amplifier is used to amplify the far-end and near-end load supply voltage difference to serve as the first current abnormal signal to be output.

7. The circuit according to claim 6, wherein the control logic component is configured to compare the amplified far-end and near-end load supply voltage difference and a preset far-end and near-end voltage difference threshold, outputs, in response to the amplified far-end and near-end load supply voltage difference exceeding the far-end and near-end voltage difference threshold, the turn-off control signal for instructing to turn off the power field effect transistor switch, and outputs, in response to the amplified far-end and near-end load supply voltage difference not exceeding the far-end and near-end voltage difference threshold, the turn-off control signal for instructing to keep turn-on of the power field effect transistor switch.

8. The circuit according to claim 1, wherein the channel conduction parameters comprise whether a channel of the power field effect transistor switch is conducted or not, a conduction degree of the channel, and a cutoff speed of the channel.

9. The circuit according to claim 8, wherein the power field effect transistor switch is configured to instruct cutoff of the circuit main current in response to the power field effect transistor cut-off signal, such that a driving electrode of the power field effect transistor switch discharges a driving electrode voltage of the power field effect transistor switch with the cutoff speed of the channel so as to reach the conduction degree of the channel, thereby cutting off the circuit main current.

10. A high-reliability power supply system, comprising:
a power supply end;
a load, comprising a near-end load and a far-end load; and
a high-reliability protection circuit, wherein the high-reliability protection circuit is electrically connected to the power supply end and the load, such that the power supply end supplies power to the load and provides high-reliability power supply protection;
wherein the high-reliability protection circuit comprising:
a load overcurrent voltage monitoring component, which is connected to two ends of a load in parallel so as to detect a load supply voltage of the load, and determines and outputs a first current abnormal signal based on the load supply voltage;
a control logic component, which is electrically connected to the load overcurrent voltage monitoring component so as to receive the first current abnormal signal and generates a turn-off control signal based on the first current abnormal signal;
a driving electrode charging charge pump component, which is electrically connected to the control logic component so as to receive the turn-off control signal, and generates a driving electrode voltage control signal and a channel conduction parameter control signal based on the turn-off control signal;
a driving electrode rapid discharge component, which is electrically connected to the driving electrode charging charge pump component so as to receive the driving electrode voltage control signal, and transmits a power field effect transistor cut-off signal based on the driving electrode voltage control signal; and
a power field effect transistor switch, which is electrically connected to the driving electrode charging charge pump component and the driving electrode rapid discharge component so as to respectively receive the channel conduction parameter control signal and the power field effect transistor cut-off signal, adjusts channel conduction parameters of the power field effect transistor switch based on the channel conduction parameter control signal, and cuts off a circuit main current based on the power field effect transistor cut-off signal.

11. The system according to claim 10, wherein the load overcurrent voltage monitoring component comprises:
a near-end supply voltage feedback component, which is connected to two ends of a near-end load in parallel so as to detect a near-end load supply voltage of the near-end load;
a far-end supply voltage feedback component, which is connected to two ends of a far-end load in parallel so as to detect a far-end load supply voltage of the far-end load; and
an H-bridge capacitor voltage difference feedback component, which is electrically connected to the near-end supply voltage feedback component and the far-end supply voltage feedback component so as to acquire the near-end load supply voltage and the far-end load supply voltage, and determines and outputs the first current abnormal signal based on the near-end load supply voltage and the far-end load supply voltage.

12. The circuit according to claim 1, wherein the H-bridge capacitor voltage difference feedback component is a structure formed by butt joint of two transistors.

13. The circuit according to claim 1, wherein the driving electrode charging charge pump component is configured to provide and control the voltage of the driving electrode so as to control turn-on and turn-off of the power field effect transistor switch.

14. The circuit according to claim 13, wherein the driving, electrode charging charge pump component is configured to provide and control the voltage of the driving, electrode so as to control an opening degree and a closing speed of the channel in the power field effect transistor switch.

15. The circuit according to claim 1, wherein the driving electrode rapid discharge component is configured to turn off the power field effect transistor switch by discharging the driving electrode charge.

16. The circuit according to claim 4, wherein the near-end supply voltage feedback component and the far-end supply voltage feedback component are configured to monitor near-end and far-end voltage abnormality according to a character that a voltage in an inductive circuit leads a current.

17. The circuit according to claim 4, wherein the near-end supply voltage feedback component and the far-end supply voltage feedback component are configured to adjust a voltage threshold to realize protection actions of slow overcurrent and transient overcurrent.

18. The circuit according to claim 4, wherein the near-end supply voltage feedback component and the far-end supply voltage feedback component are equipped with a filter capacitive device.

19. The circuit according to claim 3, wherein the control logic component is configured to receive current information from the front-end current monitoring component, to achieve monitoring functions with external current values or power.

20. The circuit according to claim 3, wherein output terminal of the driving electrode charging charge pump component is connected to the driving pole of the power field-effect transistor switch, and output terminal of the driving electrode rapid discharge component is connected to the driving pole of the power field effect transistor switch.
